(19) United States
(12) Patent Application Publication
(10) Pub. No.: US 2026/0367162 A1
(43) Pub. Date: Nov. 19, 2026

(54) SOC ESTIMATION DEVICE

(71) Applicant: SUBARU CORPORATION, Tokyo (JP)

(72) Inventors: Mami OSAWA, Tokyo (JP); Daichi AKIYAMA, Tokyo (JP)

(21) Appl. No.: 19/515,865

(22) PCT Filed: Sep. 25, 2023
(86) PCT No.: PCT/JP2023/034780

§ 371 Date: Mar. 3, 2026

(51) Int. Cl. G01R 31/3842; B60L 3/00; B60L 58/12; G01R 31/3828

(52) U.S. Cl. CPC G01R 31/3842; B60L 3/0046; B60L 58/12; G01R 31/3828

(57) ABSTRACT

A processor of an SOC estimation device executes a process including the following. Plot data in which a correction index corresponding to a trip period to which an end-time SOC belongs is associated with an absolute current amount integrated value up to the trip period to which the end-time SOC belongs is generated. It is determined whether polarization of a battery is eliminated at a start time of the trip period. When it is determined that the polarization of the battery is not eliminated, an estimated value of the correction index corresponding to a trip period immediately before a trip period to which a current time point belongs is derived based on the plot data in a past. An initial value of an SOC in the trip period to which the current time point belongs is derived based on the estimated value of the correction index.

### TECHNICAL FIELD

The present invention relates to an SOC (State Of Charge) estimation device for estimating an SOC of a battery.

### BACKGROUND ART

For example, PTL 1 discloses a technique for estimating the soc by an open-circuit voltage method and a technique for estimating the SOC by a current integration method. In PTL 1, a reference time is set by using a total error obtained by adding an error value of the SOC obtained by the open-circuit voltage method and an error value of the Soc obtained by the current integration method, and the soc is estimated by using the set reference time.

### CITATION LIST

### Patent Literature

PTL 1: Japanese Unexamined Patent Application Publication No. 2014-202551

### SUMMARY OF INVENTION

### Technical Problem

In the current integration method, the amount of change in the SOC with respect to an initial value of the SOC is derived based on a current integrated value, and the initial value of the SOC is added to the amount of change in the SOC to estimate the SOC. The initial value of the SOC is estimated by, for example, the open-circuit voltage method. However, for example, when the polarization of the battery is not eliminated, it is difficult to estimate an appropriate initial value of the SOC by the open-circuit voltage method.

Therefore, an object of the present invention is to provide an SOC estimation device capable of estimating the appropriate initial value of the soc.

### Solution to Problem

In order to solve the above problem, an SOC estimation device according to an embodiment of the present invention includes:
a battery to be mounted on a vehicle; and
a control device configured to estimate an SOC of the battery, in which
the control device includes:
at least one processor; and
at least one memory coupled to the at least one processor,
a period from ready-on to ready-off of the vehicle is a trip period, and
the at least one processor is configured to execute a process including:
deriving a difference between an end-time SOC that is an SOC estimated by a current integration method at an end time of the trip period and a start-time SOC that is an SOC estimated by an open-circuit voltage method at a start time of the trip period following the trip period to which the end-time SOC belongs, as an SOC correction amount indicating an estimation error of the SOC corresponding to the trip period to which the end-time SOC belongs;
deriving an absolute current amount that is a value obtained by adding an integrated value of an absolute value of a charging current in the battery and an integrated value of an absolute value of a discharging current in the battery in the trip period;
dividing the SOC correction amount corresponding to the trip period to which the end-time SOC belongs by the absolute current amount in the trip period to which the end-time SOC belongs to derive a correction index corresponding to the trip period to which the end-time SOC belongs;
deriving an absolute current amount integrated value that is a value obtained by integrating the absolute current amount over a plurality of the trip periods from a predetermined reference time point;
generating plot data in which the correction index corresponding to the trip period to which the end-time SOC belongs is associated with the absolute current amount integrated value up to the trip period to which the end-time SOC belongs;
performing a determination of whether polarization of the battery is eliminated at the start time of the trip period;
when it is determined that the polarization of the battery is not eliminated, deriving an estimated value of the correction index corresponding to the trip period immediately before the trip period to which a current time point belongs, based on the plot data in a past; and
deriving an initial value of the soc in the trip period to which the current time point belongs, based on the estimated value of the correction index.

### Advantageous Effects of Invention

According to the present invention, it is possible to estimate the appropriate initial value of the SOC.

### BRIEF DESCRIPTION OF DRAWINGS

FIG. 1 is a schematic block diagram illustrating a configuration of a vehicle to which an SOC estimation device according to the present embodiment is applied.

FIG. 2 is a diagram illustrating an example of estimation methods and estimation timings of an SOC.

FIG. 3 is a diagram illustrating another example of the estimation methods and the estimation timings of the SOC.

FIG. 4 is a diagram illustrating derivation of an SOC initial value based on an estimated value of a correction index.

FIG. 5 is a diagram illustrating a relationship between the correction index and allowable electric power.

FIG. 6 is a diagram illustrating an example of pieces of plot data in a case where a tendency of transition of the correction index in accordance with transition of an absolute current amount integrated value is an increasing tendency.

FIG. 7 is a diagram illustrating an example of pieces of plot data in a case where the tendency of the transition of the correction index in accordance with the transition of the absolute current amount integrated value is a decreasing tendency.

FIG. 8 is a diagram illustrating an example of pieces of plot data in a case where the tendency of the transition of (the correction index in accordance with the transition of the absolute current amount integrated value is substantially constant.

FIG. 9 is a flowchart illustrating a flow of operation of an SOC estimator.

FIG. 10 is a flowchart illustrating a flow of a process periodically and repeatedly executed by the soc estimator until the vehicle is brought into a ready-off state after a process in FIG. 9.

FIG. 11 is a flowchart illustrating a flow of an SOC initial value derivation process.

FIG. 12 is a flowchart illustrating a flow of a full charge capacity update determination process.

FIG. 13 is a flowchart illustrating a flow of a correction value derivation process.

### DESCRIPTION OF EMBODIMENTS

Hereinafter, an embodiment of the present invention will be described in detail with reference to the accompanying drawings. Specific dimensions, materials, numerical values, and the like illustrated in the embodiment are merely examples for facilitating understanding of the invention, and do not limit the present invention unless otherwise specified. In this specification and the drawings, elements having substantially the same functions and configurations are denoted by the same reference numerals to omit redundant description, and elements not directly related to the present invention are not illustrated.

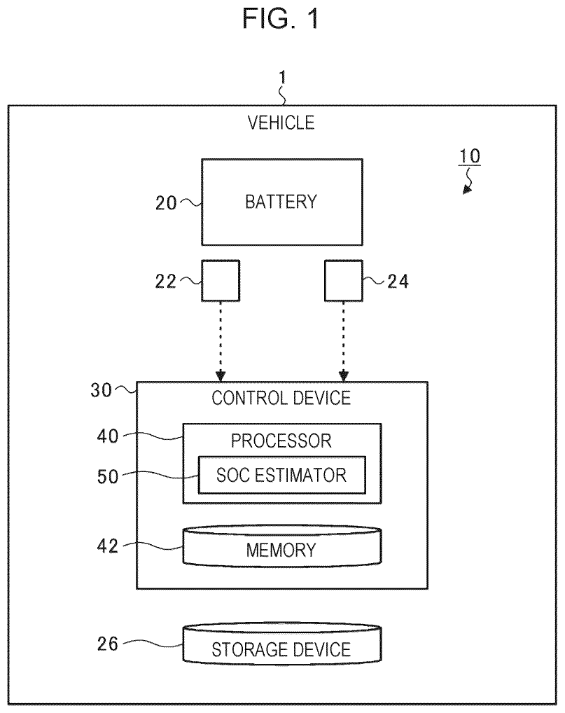

FIG. 1 is a schematic block diagram illustrating a configuration of a vehicle 1 to which an SOC estimation device 10 according to the present embodiment is applied. The vehicle 1 is, for example, an electric vehicle including a motor generator as a drive source. Note that the vehicle 1 may be a hybrid electric vehicle including an engine and a motor generator as drive sources.

The vehicle 1 includes a battery 20, a voltage sensor 22, a current sensor 24, a storage device 26, and a control device 30.

The battery 20 is, for example, a chargeable and dischargeable secondary battery such as a lithium ion battery. Note that the battery 20 is not limited to the lithium ion battery, and may be made of any known chargeable and dischargeable composition. The battery 20 is mounted on the vehicle 1. The battery 20 is a high-voltage battery for example, and supplies electric power to the motor generator. In addition, the battery 20 is charged with electric power regenerated by the motor generator serving as a generator. The vehicle 1 may have a configuration in which the battery 20 can be charged with electric power supplied from the outside of the vehicle 1.

The voltage sensor 22 is configured to be capable of detecting the voltage of the battery 20. For example, in a state where the battery 20 is electrically disconnected from an electric system of the vehicle 1, the voltage sensor 22 can detect an open-circuit voltage of the battery 20. Hereinafter, the open-circuit voltage may be referred to as OCV.

The current sensor 24 is configured to be capable of detecting a charging current to be input to the battery 20 and a discharging current output from the battery 20.

The storage device 26 is constituted by a non-volatile storage element. Note that the non-volatile storage element may include an electrically readable and writable non-volatile storage element or the like, such as a flash memory. The storage device 26 can store, for example, various kinds of information and data related to the estimation of the SOC of the battery 20.

The control device 30 includes at least one processor 40 and at least one memory 42 coupled to the at least one processor 40. The at least one memory 42 includes a ROM in which a program or the like is stored and a RAM as a work area. The at least one processor 40 of the control device 30 controls the entirety of the vehicle 1 in cooperation with the program included in the at least one memory 42.

In more detail, the at least one processor 40 serves as an SOC estimator 50 that estimates the SOC (State Of Charge) of the battery 20 in cooperation with the program. Note that the SOC indicates a charge rate expressed by a percentage of a current charge capacity to a full charge capacity of the battery 20.

The SOC estimator 50 can estimate the soc by an open-circuit voltage method, and can also estimate the SOC by a current integration method. Hereinafter, the open-circuit voltage method may be referred to as an OCV method.

The open-circuit voltage method is an estimation method for estimating the SOC, based on the open-circuit voltage of the battery 20. For example, an open-circuit voltage SOC map, which is a map in which the open-circuit voltage and the SOC are associated with each other on a one-to-one basis, is stored in the at least one memory 42 in advance. In the open-circuit voltage method, the SOC estimator 50 applies the open-circuit voltage of the battery 20 detected by the voltage sensor 22 to the open-circuit voltage SOC map to derive the soc.

The current integration method is an estimation method for estimating the SOC, based on a current integrated value obtained by integrating the charging current and the discharging current of the battery 20 with the passage of time. In the current integration method, the SOC estimator 50 acquires the charging current and the discharging current of the battery 20, which change with the passage of time due to the traveling of the vehicle 1, by the current sensor 24. The SOC estimator 50 integrates the acquired charging current and discharging current as appropriate to derive the current integrated value. The SOC estimator 50 divides the current integrated value by the full charge capacity to derive the amount of change from an initial value of the SOC. The SOC estimator 50 adds the initial value to the derived amount of change from the initial value to derive a current SOC.

Thus, in the current integration method, the estimation accuracy of the soc depends on three parameters, which are the current integrated value, the full charge capacity, and the initial value of the SOC. On the other hand, in the open-circuit voltage method, since the open-circuit voltage SOC map is determined in advance, the estimation accuracy of the Soc depends on the open-circuit voltage detected by the voltage sensor 22. Therefore, the estimation accuracy of the SOC can be made higher in the open-circuit voltage method than in the current integration method.

Since the open-circuit voltage is detected in a state where the battery 20 is disconnected from the electric system of the vehicle 1, the timing at which the SOC can be estimated by the open-circuit voltage method is restricted. On the other hand, in the current integration method, the SOC can be estimated even when the vehicle 1 is traveling, and the SOC can be estimated without hindering the traveling of the vehicle 1.

Since the open-circuit voltage method and the current integration method have the above-described characteristics, the estimation by the open-circuit voltage method and the estimation by the current integration method are selectively used depending on the situation.

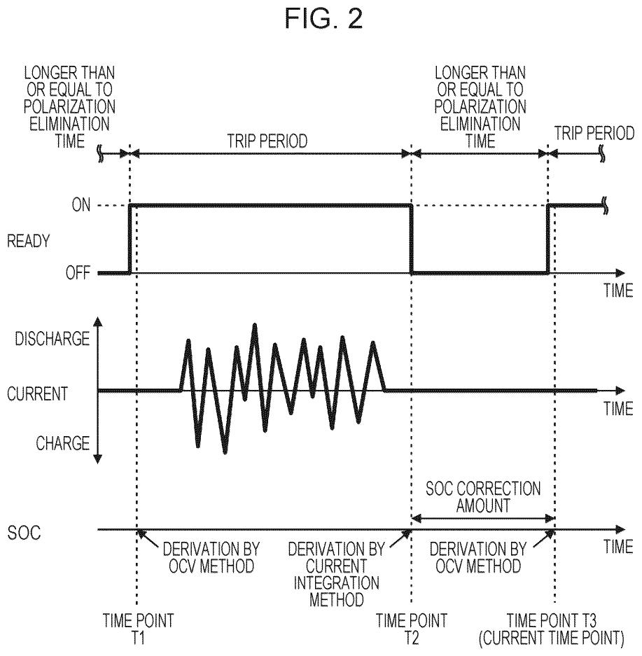

FIG. 2 is a diagram illustrating an example of estimation methods and estimation timings of the SOC. Hereinafter, a period from ready-on to ready-off of the vehicle 1 may be referred to as a trip period. That is, a start time point of the trip period is a time point at which the vehicle 1 is brought into a ready-on state, and an end time point of the trip period is a time point at which the vehicle 1 is brought into a ready-off state.

As illustrated in FIG. 2, since the battery 20 is charged and discharged as the vehicle 1 travels during the trip period, the current of the battery 20 changes.

When the battery 20 is charged, polarization occurs inside the battery 20. The polarization is a phenomenon in which electrons are biased between a positive electrode and a negative electrode of the battery 20 and a pseudo potential difference appears. When such polarization occurs, the voltage of the battery 20 detected by the voltage sensor 22 is higher than an actual voltage by the pseudo potential difference. As a result, the accuracy of the SOC derived by the open-circuit voltage method using the detection result of the voltage sensor 22 is reduced.

Such polarization can be eliminated by waiting for a predetermined time in a state where charging is not performed after charging of the battery 20. In view of this, the polarization of the battery 20 is eliminated when the next ready-on state is set after a predetermined time during which the polarization can be eliminated has elapsed from the timing of ready-off of the vehicle 1.

Hereinafter, the time during which the polarization can be eliminated may be referred to as a polarization elimination time. The polarization elimination time is 30 minutes or the like for example, but may be any time during which the polarization can be eliminated in consideration of the type and performance of the battery 20.

When the polarization is eliminated, the pseudo potential difference substantially disappears, and the detection result of the voltage sensor 22 and the actual voltage become substantially the same. That is, by eliminating the polarization, it is possible to suppress a decrease in the accuracy of the SOC derived by the open-circuit voltage method using the detection result of the voltage sensor 22.

In the example in FIG. 2, a time point T1 corresponds to a time point at which the ready-on state is set, and is a time point at which a time longer than or equal to the polarization elimination time has elapsed from ready-off in the preceding trip period. A time point T2 corresponds to a time point of ready-off in the trip period to which the time point T1 belongs. A time point T3 corresponds to a time point at which the ready-on state is set subsequently to the trip period to which the time point T1 belongs, and is a time point at which a time longer than or equal to the polarization elimination time has elapsed from the time point T2.

In addition, in the example in FIG. 2, it is assumed that the time point T3 is a current time point. Hereinafter, the trip period to which the current time point belongs may be referred to as a current trip period. A trip period immediately before the trip period to which the current time point belongs may be referred to as a last-time trip period. In the example in FIG. 2, the trip period to which the time point T3 belongs is the current trip period, and the trip period to which the time point T1 and the time point T2 belong is the last-time trip period.

As described above, since the decrease in the accuracy of the Soc by the OCV method can be suppressed if the polarization is eliminated, the SOC estimator 50 determines whether the polarization of the battery 20 is eliminated at the time of ready-on. When the polarization of the battery 20 is eliminated, the SOC estimator 50 derives the soc by the OCV method.

In the example in FIG. 2, since a time longer than or equal to the polarization elimination time has elapsed before the time point T1, the SOC estimator 50 can derive the soc by the OCV method at the time point T1 of ready-on. In addition, since a time longer than or equal to the polarization elimination time has elapsed before the time point T3, the SOC estimator 50 can derive the SOC by the OCV method at the time point T3 of ready-on.

In addition, since the current integrated value is derived during the trip period, the SOC estimator 50 can derive the SOC by the current integration method at the time point T2.

When the battery 20 is repeatedly charged and discharged, deterioration of the battery 20 may progress. When the deterioration of the battery 20 progresses, the full charge capacity of the battery 20 may decrease. The full charge capacity can be derived when the battery 20 is fully charged. When the battery 20 is deteriorated, it is desirable to derive and update the full charge capacity.

However, when the full charge capacity decreases during the trip period, the possibility that the full charge capacity is updated during the trip period is low. Therefore, in the current integration method, the SOC is estimated by using the full charge capacity before the decrease. Then, the SOC obtained by the current integration method at the end time of the trip period may have a value different from the actual SOC due to the decrease in the full charge capacity. For example, in the example in FIG. 2, when the full charge capacity decreases during the last-time trip period between the time point T1 and the time point T2, the value of the SOC obtained by the current integration method at the time point T2 may be different from an actual value.

On the other hand, the SOC obtained by the OCV at the time point T3, which is the start time of the current trip period is estimated without using the full charge capacity. Thus, even if the full charge capacity decreases during the last-time trip period, the soc obtained by the OCV becomes the actual value reflecting the decrease in the full charge capacity.

In addition, as illustrated in FIG. 2, the current of the battery 20 does not change between the time point T2 and the time point T3. Thus, the actual SOC at the time point T2 and the actual SOC at the time point T3 ideally have the same value. Then, the SOC obtained by the OCV method at the time point T3 can be regarded as the SOC at the time point T2.

In view of this, the present embodiment introduces a concept of an SOC correction amount. The SOC correction amount corresponds to a deviation amount of the SOC between the end time point of the trip period and the start time point of the next trip period. Herein, for convenience of description, the SOC estimated by the current integration method at the end time of the trip period may be referred to as an end-time SOC. The SOC estimated by the open-circuit voltage method at the start time of the trip period subsequent to the trip period to which the end-time soc belongs may be referred to as a start-time SOC.

The SOC correction amount is derived from the difference between the end-time SOC and the start-time SOC described above (SOC correction amount=end-time SOC start-time SOC). In the example in FIG. 2, the SOC correction amount is a difference between the SOC obtained by the current integration method at the time point T2 and the SOC obtained by the OCV method at the time point T3. The SOC correction amount indicates an estimation error of the SOC corresponding to the trip period to which the end-time SOC belongs.

As described above, it is assumed that the full charge capacity decreases during the trip period between the time point T1 and the time point T2. In addition, as described above, the SOC obtained by the OCV method at the time point T3 can be regarded as the SOC at the time point T2. In this case, the SOC correction amount corresponds to an SOC error between the SOC obtained by the current integration method, in which the decrease in the full charge capacity is not reflected, and the actual soc obtained by the OCV method in which the decrease in the full charge capacity is reflected. In other words, the SOC correction amount corresponds to the estimation error of the SOC from the actual SOC due to the decrease in the full charge capacity during the trip period.

In addition, the SOC correction amount at the time the SOC correction amount is derived corresponds to the trip period immediately before the trip period to which the time the SOC correction amount is derived belongs.

The present embodiment further introduces a concept of an absolute current amount. The absolute current amount is a value obtained by adding an integrated value of an absolute value of the charging current in the battery 20 and an integrated value of an absolute value of the discharging current in the battery 20. The absolute current amount is derived during the trip period, and is derived for each trip period. The absolute current amount indicates how much the battery 20 is charged and discharged during one trip period.

Note that the current integrated value in the current integration method is integrated, for example, with the discharging current as a positive value and the charging current as a negative value. On the other hand, since the absolute current amount uses the absolute value for both the charging current and the discharging current, both the charging current and the discharging current are integrated as positive values.

The present embodiment further introduces a concept of a correction index based on the SOC correction amount and the absolute current amount. The correction index is derived by dividing the SOC correction amount corresponding to the trip period to which the end-time SOC belongs by the absolute current amount during the trip period to which the end-time SOC belongs (correction index=SOC correction amount/absolute current amount). The correction index corresponds to the trip period to which the end-time soc belongs.

In the example in FIG. 2, the correction index is derived by dividing the SOC correction amount corresponding to the last-time trip period derived at the time point T3, which is the current time point, by the absolute current amount at time point T2, which is the end time point of the last-time trip period.

The correction index is obtained by removing the influence of charging and discharging during the trip period from the estimation error of the SOC in the trip period immediately before the time point at which the correction index is derived.

The present embodiment further introduces a concept of an absolute current amount integrated value based on the absolute current amount. The absolute current amount integrated value is a value obtained by integrating the absolute current amount over trip periods from a predetermined reference time point. For example, when three trip periods have elapsed from the predetermined reference time point, the sum of the absolute current amount in a first trip period, the absolute current amount in a second trip period, and the absolute current amount in a third trip period is the absolute current amount integrated value.

As described above, since the SOC correction amount indicates the estimation error of the SOC caused by the decrease in the full charge capacity, the soc correction amount is a value related to the decrease in the full charge capacity. In view of this, it is assumed that the predetermined reference time point in the above-described absolute current amount integrated value is the time point at which the full charge capacity of the battery 20 is updated last time.

The present embodiment further introduces a concept of plot data based on the correction index and the absolute current amount integrated value. The plot data is data in which the correction index corresponding to the trip period to which the end-time SOC belongs and the absolute current amount integrated value up to the trip period to which the end-time SOC belongs are associated with each other. The plot data corresponds to the trip period to which the end-time SOC belongs, as well as the associated correction index.

The plot data at the time point the plot data is generated corresponds to the trip period immediately before the trip period to which the time point the plot data is generated belongs.

In the example in FIG. 2, the plot data corresponding to the last-time trip period is generated by associating the correction index corresponding to the last-time trip period derived at the time point T3, which is the current time point, with the absolute current amount integrated value up to the last-time trip period.

In the present embodiment, when it is determined that the polarization of the battery 20 is eliminated, the SOC estimator 50 derives the SOC correction amount, derives the correction index, and generates the plot data. The derived SOC correction amount, correction index, and plot data are stored and accumulated in the storage device 26.

Since the SOC derived by the OCV method is used for deriving the SOC correction amount, the SOC correction amount is derived as long as the polarization of the battery 20 is eliminated. In addition, since the SOC correction amount is used for deriving the correction index and the correction index is used for the plot data, the correction index and the plot data are derived as long as the polarization of the battery 20 is eliminated, similarly to the SOC correction amount. In other words, when the polarization of the battery 20 is not eliminated, the plot data is not generated.

In more detail, the SOC estimator 50 may derive the soc correction amount, the correction index, and the plot data when both of specific first and second conditions are satisfied in addition to the elimination of the polarization of the battery 20.

The specific first condition is that the SOC is estimated by the open-circuit voltage method at the start time of the trip period immediately before the trip period to which the current time point belongs. In the example in FIG. 2, since the SOC is estimated by the OCV method at the time point T1 corresponding to the start time of the trip period immediately before the current time point, the specific first condition described above is satisfied.

If the SOC is estimated by the OCV method at the start time of the trip period, by using the estimated SOC as the initial value, the initial value of the SOC in the trip period can be accurately acquired. Therefore, it is assumed that the SOC obtained by the current integration method in the trip period is estimated with relatively high accuracy. Then, since the SOC estimated with relatively high accuracy by the current integration method is used as the SOC at the end time of the trip period, the accuracy of the soc correction amount can be improved.

The specific second condition is that the period from the end time point of the trip period immediately before the trip period to which the current time point belongs to the trip period to which the current time point belongs is within a predetermined period. Hereinafter, for convenience of description, the period from the end time point of the trip period immediately before the trip period to which the current time point belongs to the trip period to which the current time point belongs may be referred to as a preceding stop period.

The predetermined period in the specific second condition is set to a period longer than the polarization elimination time. The predetermined period is set to seven days or the like for example, but can be set to an appropriate period in consideration of self-discharge of the battery 20.

If the preceding stop period is excessively long, the self-discharge of the battery 20 progresses. When the self-discharge progresses, for example, the actual SOC at the time point T3 may substantially change from the actual SOC at the time point T2. Then, the SOC of the OCV method at the time point T3 may deviate from the actual SOC at the time point T2. As a result, the accuracy of the soc correction amount may decrease.

In view of this, by deriving the SOC correction amount as long as the preceding stop period is not excessively long under the specific second condition, it is possible to suppress a decrease in the accuracy of the SOC correction amount. As a result, it is also possible to suppress a decrease in the accuracy of the correction index and the plot data.

Note that an example has been described herein in which the SOC correction amount, the correction index, and the plot data are derived when the three conditions are satisfied. The three conditions are the elimination of the polarization of the battery 20, the satisfaction of the specific first condition, and the satisfaction of the specific second condition. However, when the decrease in the accuracy of the SOC correction amount or the like is allowable, the SOC estimator 50 may omit the specific first and second conditions. In addition, at least when the polarization of the battery 20 is eliminated, the soc estimator 50 may derive the SOC correction amount, the correction index, and the plot data.

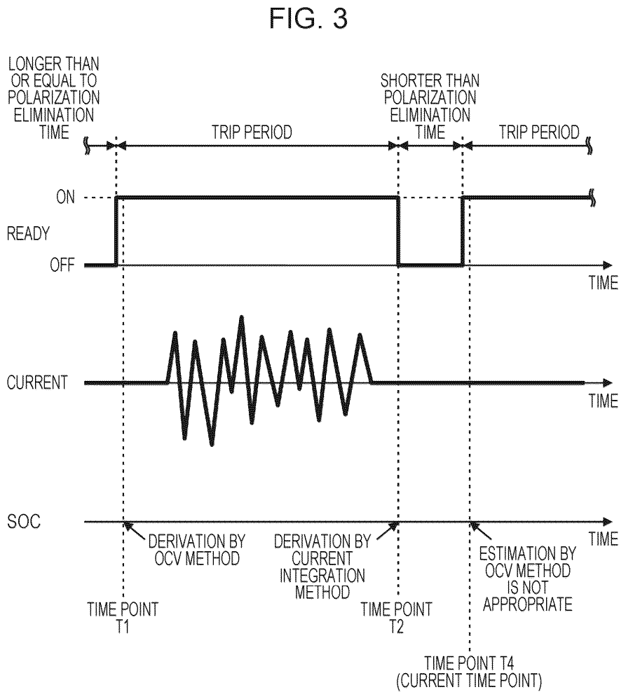

FIG. 3 is a diagram illustrating another example of the estimation methods and the estimation timings of the SOC. In FIG. 3, the period from time point T1 to time point T2 is the same as that in FIG. 2. FIG. 3 illustrates a case where ready-on is set at a time point T4 before the polarization elimination time elapses after the time point T2, and the next trip period is started. In FIG. 3, it is assumed that the time point T4 is the current time point.

When ready-on is set before the polarization elimination time elapses, there is a possibility that the polarization of the battery 20 is not eliminated. In such a case, as illustrated in FIG. 3, it is not appropriate to estimate the SOC by the OCV method at the time point T4, which is the current time point.

Therefore, in the present embodiment, when the soc estimator 50 determines that the polarization of the battery 20 is not eliminated, the SOC estimator 50 derives an estimated value of the correction index corresponding to the trip period immediately before the trip period to which the current time point belongs, based on the plot data in the past. The SOC estimator 50 derives the initial value of the SOC in the trip period to which the current time point belongs, based on the derived estimated value of the correction index. Hereinafter, the initial value of the soc may be referred to as an SOC initial value.

In more detail, since the polarization of the battery 20 is not eliminated at the start time of the current trip period, it is not possible to derive the SOC by the OCV method appropriately, and to derive the correction index corresponding to the last-time trip period from a definitional equation. Therefore, the SOC estimator 50 estimates the correction index corresponding to the last-time trip period, based on the plot data in the past.

By estimating the correction index corresponding to the last-time trip period, the degree of the estimation error of the SOC in the last-time trip period is known. Then, if the absolute current amount in the last-time trip period is considered, the end-time SOC reflecting the estimation error of the SOC in the last-time trip period can be obtained.

Ideally, the SOC at the end time of the last-time trip period can be regarded as substantially the same as the soc at the start time of the current trip period. Therefore, by deriving the SOC at the end time of the last-time trip period, based on the estimated value of the correction index corresponding to the last-time trip period, it is possible to substantially derive the SOC at the start time of the current trip period. The SOC at the start time of the current trip period derived in this way can be used as the initial value of the SOC in the current trip period.

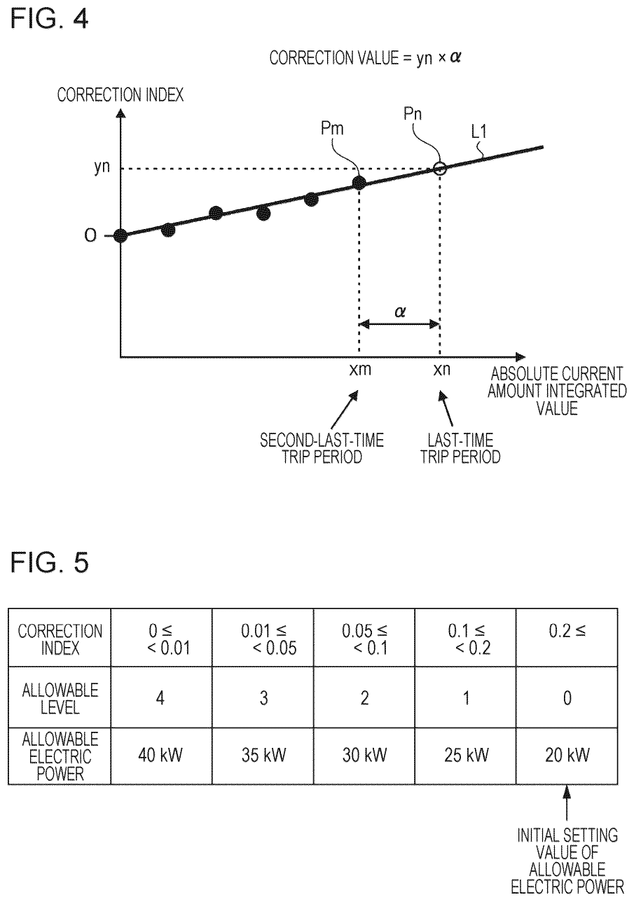

FIG. 4 is a diagram illustrating derivation of the SOC initial value based on the estimated value of the correction index. In FIG. 4, the horizontal axis indicates the absolute current amount integrated value from the predetermined reference time point, for example, a time point at which the full charge capacity is updated. The vertical axis represents the correction index.

The black circles in FIG. 4 indicate pieces of plot data in the past generated at and after the predetermined reference time point. Plot data Pm is a piece of plot data in the past closest to the current time point among pieces of plot data in the past. Plot data Pn indicated by the white circle indicates an estimated value of plot data corresponding to the last-time trip period. Note that the white circle corresponds to the current time point from the viewpoint of the estimation timing of the correction index and the plot data.

In the example in FIG. 4, an absolute current amount integrated value xn is an absolute current amount integrated value up to the trip period immediately before the trip period to which the current time point belongs, that is, the last-time trip period. An absolute current amount integrated value xm is an absolute current amount integrated value corresponding to the piece of plot data closest to the current time point among the pieces of plot data in the past. The trip period corresponding to the piece of plot data closest to the current time point among the pieces of plot data in the past is, for example, a second-last-time trip period that is immediately before the last-time trip period.

In addition, in the example in FIG. 4, a differential absolute current amount integrated value α is a difference between the absolute current amount integrated value xn and the absolute current amount integrated value xm (α=xn−xm). In other words, the absolute current amount integrated value xn is a value obtained by adding the differential absolute current amount integrated value α to the absolute current amount integrated value xm (xn=xm+α).

For example, when the absolute current amount integrated value xm is the absolute current amount integrated value in the second-last-time trip period, the differential absolute current amount integrated value α corresponds to the absolute current amount in the last-time trip period. Therefore, the differential absolute current amount integrated value α is known at the time point the correction index is estimated. The absolute current amount integrated value xm is also known at the time point the correction index is estimated.

In addition, in the example in FIG. 4, a correction index yn is the estimated value of the correction index corresponding to the last-time trip period.

The SOC estimator 50 derives an approximate expression of pieces of plot data in the past by using the pieces of the plot data in the past. The approximate expression is, for example, a linear function (y=ax+b). A line L1 in FIG. 4 is an example of the approximate expression.

The SOC estimator 50 substitutes a value “xm+α” obtained by adding the differential absolute current amount integrated value α for the absolute current amount integrated value xm in the approximate expression to derive the correction index yn, which is the estimated value.

The SOC estimator 50 multiplies the derived estimated value of the correction index, that is, the correction index yn, by the differential absolute current amount integrated value α to derive a correction value (correction value=yn×α). Since the correction index includes information of the SOC correction amount, the correction index includes information of the estimation error of the SOC due to the decrease in the full charge capacity. Therefore, the correction value is a value including the influence of the decrease in the full charge capacity in the last-time trip period.

Herein, for convenience of description, the trip period corresponding to the piece of plot data closest to the current time among the pieces of plot data in the past may be referred to as the trip period of the last-time plot data. In addition, the SOC derived by the open-circuit voltage method in the trip period of the last-time plot data may be referred to as the soc obtained by the last-time OCV.

The SOC estimator 50 adds the derived correction value to the end-time SOC derived at the end time of the last-time trip period to derive the SOC initial value (SOC initial value=last-time end-time SOC+correction value). As described above, since the correction value includes the influence of the decrease in the full charge capacity in the last-time trip period, the SOC initial value is a value reflecting the influence of the decrease in the full charge capacity.

In this way, when it is determined that the polarization is not eliminated, the initial value of the SOC is derived based on the estimated value of the correction index. Thus, even when the polarization is not eliminated, the initial value of the SOC can be accurately derived.

In FIG. 4, an example in which the trip period of the last-time plot data is the second-last-time trip period is described. However, the trip period of the last-time plot data may be a trip period before the second-last-time trip period. That is, between the trip period of the last-time plot data and the current trip period, there may be one or more trip periods in which the polarization is not eliminated and it is not possible to generate the plot data.

If the number of trip periods in which it is not possible to generate the plot data increases between the trip period of the last-time plot data and the current trip period, the accuracy of the approximate expression may decrease.

Therefore, the SOC estimator 50 may determine whether the number of trip periods between the trip period of the last-time plot data and the trip period immediately before the trip period to which the current time point belongs is less than a predetermined number. Hereinafter, for convenience of description, a period between the trip period of the last-time plot data and the trip period immediately before the trip period to which the current time point belongs may be referred to as a period between the trip period of the last-time plot data and the last-time trip period.

The SOC estimator 50 may derive the estimated value of the correction index and derive the initial value of the SOC based on the estimated value of the correction index when the number of trip periods in the period between the trip period of the last-time plot data and the last-time trip period is less than the predetermined number. The predetermined number is set to three or the like for example, but can be set to any number based on the tolerance of the accuracy of the approximate expression.

In this way, by performing a determination condition of the number of trip periods in the period between the trip period of the last-time plot data and the last-time trip period, it is possible to suppress a decrease in the accuracy of the approximate expression. As a result, it is possible to suppress a decrease in the accuracy of the estimated value of the correction index and the correction value.

Note that the determination condition of the number of trip periods in the period between the trip period of the last-time plot data and the last-time trip period may be omitted.

An upper limit value of an absolute value of electric power allowed to be input to the battery 20 may be referred to as allowable input electric power. An upper limit value of an absolute value of electric power allowed to be output from the battery 20 may be referred to as allowable output electric power. The allowable input electric power and the allowable output electric power may be collectively referred to as allowable electric power. That is, the allowable electric power means at least one of the allowable input electric power and the allowable output electric power.

Such allowable electric power is set in the battery 20. An estimated value of the SOC herein may be a value higher than the actual SOC by an error. Then, the allowable electric power is set to a relatively low value with a margin corresponding to the error of the SOC with respect to the actual SOC.

In the present embodiment, the SOC estimator 50 changes the value of the allowable electric power of the battery 20, based on the correction index.

FIG. 5 is a diagram illustrating a relationship between the correction index and the allowable electric power. For example, the at least one memory 42 stores in advance an allowable electric power map in which the correction index and the allowable electric power are associated with each other on a one-to-one basis, as illustrated in FIG. 5. Note that the numerical values illustrated in FIG. 5 are examples, and each numerical value in the allowable electric power map may be set to any value in consideration of the type, specification, and the like of the battery 20.

An allowable level indicates the level of the allowable electric power. The allowable level “0” corresponds to an initial setting value of the allowable electric power. As illustrated in FIG. 5, the allowable level and the allowable electric power are associated with each other such that the allowable electric power increases as the allowable level increases.

As described above, as the correction index decreases, the estimation error of the SOC decreases. In view of this, in the allowable electric power map, the correction index and the allowable electric power are associated with each other such that the allowable electric power increases as the correction index decreases.

The SOC estimator 50 applies the derived correction index to the allowable electric power map to derive the allowable electric power. When the allowable electric power is derived in this way by using the allowable electric power map, the allowable electric power can be made larger than the initial setting value of the allowable electric power as the correction index decreases. In other words, the allowable electric power can be relaxed from the initial setting value of the allowable electric power.

That is, in the present embodiment, since the degree of the estimation error of the SOC can be grasped by the correction index, the margin in the allowable electric power can be set to an appropriate value in accordance with the degree of the estimation error of the SOC.

Therefore, when the estimated value of the soc is derived such that the estimation error of the SOC decreases, it is possible to suppress excessive restriction of the allowable electric power. As a result, as the allowable electric power increases, the driving performance of the vehicle 1 can be improved.

In the present embodiment, the SOC estimator 50 may determine whether the full charge capacity is to be updated based on pieces of plot data from the predetermined reference time point.

In addition, in the present embodiment, the soc estimator 50 may determine whether an abnormality related to the derivation of the SOC has occurred based on the pieces of plot data from the predetermined reference time point.

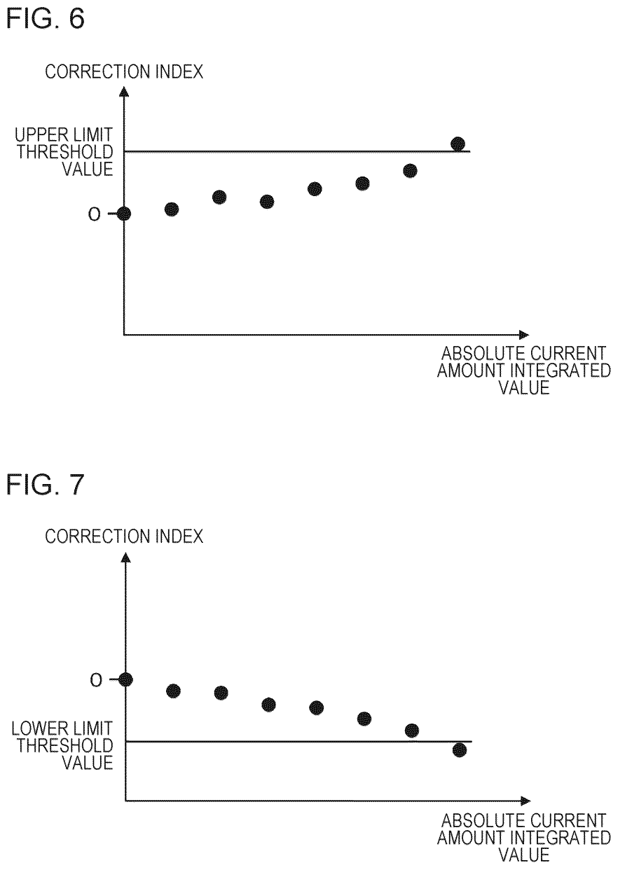

FIG. 6 is a diagram illustrating an example of pieces of plot data in a case where a tendency of transition of the correction index in accordance with transition of the absolute current amount integrated value is an increasing tendency.

For example, an approximate expression of the pieces of plot data may be derived, and when the inclination of the approximate expression is a positive value greater than or equal to a predetermined value, it may be determined that the tendency of the transition of the correction index in accordance with the transition of the absolute current amount integrated value is the increasing tendency. Note that the method of determining the tendency of the transition is not limited to the method using the approximate expression, and any known method such as a method of determining the tendency of the transition based on a moving average of the pieces of plot data can be used.

When the tendency of the transition of the correction index in accordance with the transition of the absolute current amount integrated value is the increasing tendency, it means that the full charge capacity of the battery 20 is gradually decreasing. Note that the gradual decrease in the full charge capacity of the battery 20 is a normal mode of deterioration and is not an abnormality.

Therefore, the SOC estimator 50 determines that the full charge capacity is to be updated when the tendency of the transition of the correction index in accordance with the transition of the absolute current amount integrated value is the increasing tendency and the most recent correction index exceeds a predetermined upper limit threshold value. The predetermined upper limit threshold value may be set to an appropriate value in consideration of the update frequency of the full charge capacity and the like.

Accordingly, it is possible to appropriately detect that the full charge capacity has decreased, and it is possible to request the update of the full charge capacity at an appropriate timing when the full charge capacity has decreased and at an appropriate frequency.

In addition, by including the condition that the tendency of the transition of the correction index in accordance with the transition of the absolute current amount integrated value is the increasing tendency, it is possible to avoid a situation. The situation is, for example, a situation in which the update of the full charge capacity is requested in vain due to an outlier such as a case where the correction index accidentally exceeds the upper limit threshold value.

Note that the condition that the correction index exceeds the upper limit threshold value is not limited to the most recent correction index, and the condition may be satisfied when the correction index exceeds the upper limit threshold value in at least one of the pieces of plot data from the predetermined reference time point.

When it is determined that the full charge capacity is to be updated, the SOC estimator 50 turns on, for example, an update request flag indicating that the full charge capacity is to be updated. Then, if the update request flag is in the ON state when a condition under which the full charge capacity can be derived is satisfied, for example, when the battery 20 is fully charged, the SOC estimator 50 derives and updates the full charge capacity.

When the ready-on state is set after the update of the full charge capacity, the SOC estimator 50 resets the absolute current amount integrated value to the initial value.

In addition, when the tendency of the transition of the correction index in accordance with the transition of the absolute current amount integrated value is the increasing tendency, it is assumed that the SOC is appropriately estimated, and thus, the SOC estimator 50 determines that there is no abnormality related to the derivation of the SOC.

FIG. 7 is a diagram illustrating an example of pieces of plot data in a case where the tendency of the transition of the correction index in accordance with the transition of the absolute current amount integrated value is a decreasing tendency.

For example, an approximate expression of the pieces of plot data may be derived, and when the inclination of the approximate expression is a negative value less than a predetermined value, it may be determined that the tendency of the transition of the correction index in accordance with the transition of the absolute current amount integrated value is the decreasing tendency.

When the tendency of the transition of the correction index in accordance with the transition of the absolute current amount integrated value is the decreasing tendency, it means that the full charge capacity is increasing from the viewpoint of the full charge capacity. In general, the full charge capacity hardly increases. Therefore, in a case of the decreasing tendency, it is assumed that some abnormality has occurred in the process of estimating the SOC.

Therefore, the SOC estimator 50 may determine that the abnormality related to the derivation of the SOC has occurred when the tendency of the transition of the correction index in accordance with the transition of the absolute current amount integrated value is the decreasing tendency and the most recent correction index falls below a predetermined lower limit threshold value. The lower limit threshold value may be set to, for example, any value in consideration of a normal variation width of the correction index.

When it is determined that the abnormality has occurred, the fact may be reported by, for example, displaying an error or the like. In addition, when it is determined that the abnormality has occurred, for example, a predetermined restriction may be imposed on the control of the vehicle 1, such as reducing the allowable electric power to be lower than the initial setting value.

Thus, it is possible to appropriately detect that the SOC is not appropriately estimated. As a result, it is possible to appropriately take measures against the abnormality related to the derivation of the SOC.

In addition, by including the condition that the tendency of the transition of the correction index in accordance with the transition of the absolute current amount integrated value is the decreasing tendency, it is possible to avoid a situation. The situation is, for example, a situation in which it is erroneously determined that the abnormality has occurred due to an outlier such as a case where the correction index accidentally exceeds the lower limit threshold value.

Note that the condition that the correction index falls below the lower limit threshold value is not limited to the most recent correction index, and the condition may be satisfied when the correction index falls below the lower limit threshold value in at least one of the pieces of plot data from the predetermined reference time point.

In addition, when the tendency of the transition of the correction index in accordance with the transition of the absolute current amount integrated value is the decreasing tendency, it is assumed that the abnormality related to the derivation of the SOC has occurred, and thus, the soc estimator 50 does note request the update of the full charge capacity.

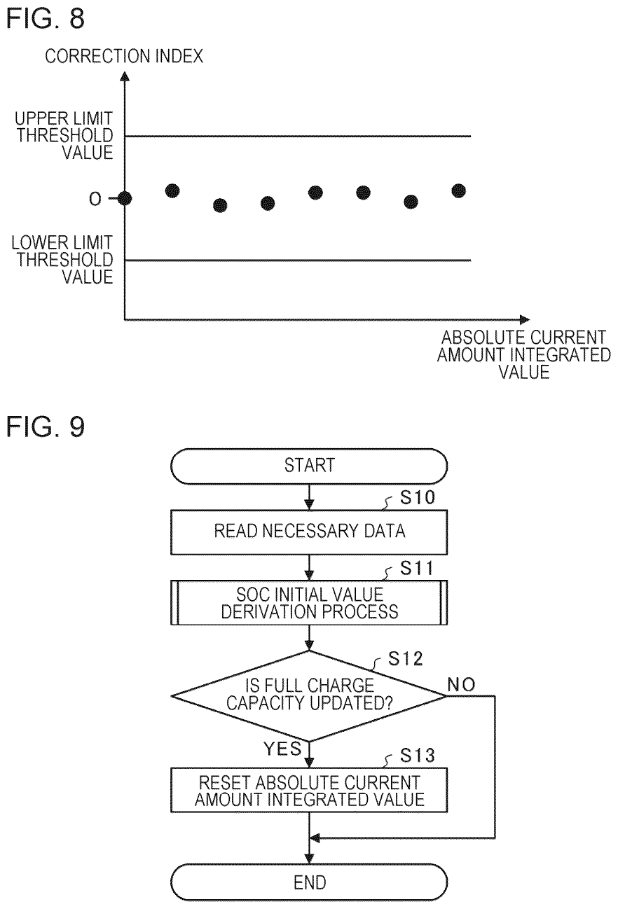

FIG. 8 is a diagram illustrating an example of pieces of plot data in a case where the tendency of the transition of the correction index in accordance with the transition of the absolute current amount integrated value is substantially constant.

For example, an approximate expression of the pieces of plot data may be derived, and when the inclination of the approximate expression is a positive value less than a predetermined value or and a negative value greater than or equal to a predetermined value, it may be determined that the tendency of the transition of the correction index in accordance with the transition of the absolute current amount integrated value is substantially constant.

When the tendency of the transition of the correction index in accordance with the transition of the absolute current amount integrated value is substantially constant, it is assumed that the full charge capacity has hardly decreased.

Therefore, the SOC estimator 50 does not request the update of the full charge capacity when the tendency of the transition of the correction index in accordance with the transition of the absolute current amount integrated value is substantially constant. For example, the SOC estimator 50 turns off the update request flag. Thus, unnecessary updating of the full charge capacity can be suppressed.

In addition, when the tendency of the transition of the correction index in accordance with the transition of the absolute current amount integrated value is substantially constant, it is assumed that the SOC is appropriately estimated, and thus, the SOC estimator 50 determines that there is no abnormality related to the derivation of the SOC.

FIG. 9 is a flowchart illustrating a flow of operation of the SOC estimator 50. The SOC estimator 50 starts a series of processes of FIG. 9 in response to the vehicle 1 being brought into the ready-on state.

When the vehicle 1 is brought into the ready-on state, the SOC estimator 50 reads various kinds of data necessary to estimate the SOC from the storage device 26 or the at least one memory 42 (S10). The read data is, for example, the absolute current amount in the last-time trip period, the absolute current amount integrated value up to the last-time trip period, and the like.

Subsequently, the SOC estimator 50 executes an SOC initial value derivation process (S11) for deriving the soc initial value in the current trip period. The SOC initial value derivation process (S11) will be described in detail later.

Subsequently, the SOC estimator 50 determines whether the full charge capacity is updated by the current time point after the execution of the series of processes in FIG. 9 last time (S12).

When it is determined that the full charge capacity is updated (YES in S12), the SOC estimator 50 resets the absolute current amount integrated value to the initial value (S13), and ends the series of processes in FIG. 9. The initial value is, for example, zero. Thus, the absolute current amount integrated value is newly integrated from the current trip period.

When it is determined that the full charge capacity is not updated (NO in S12), the SOC estimator 50 ends the series of processes in FIG. 9.

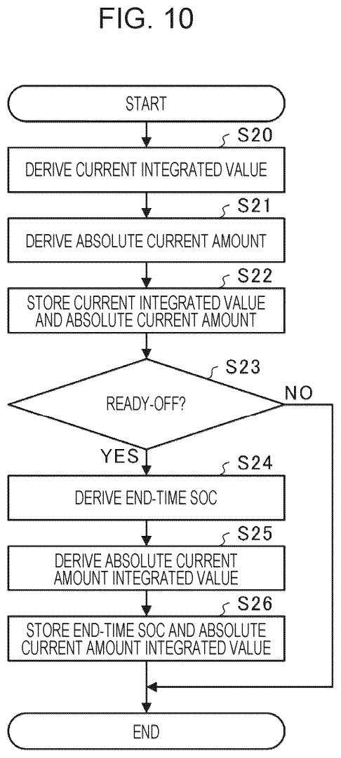

FIG. 10 is a flowchart illustrating a flow of a process periodically and repeatedly executed by the SOC estimator 50 until the vehicle 1 is brought into the ready-off state after the process in FIG. 9.

At a predetermined execution timing, the SOC estimator 50 derives the current integrated value in the current trip period, based on the current detected by the current sensor 24 (S20). Subsequently, the SOC estimator 50 derives the absolute current amount in the current trip period, based on the current detected by the current sensor 24 (S21). The SOC estimator 50 stores the derived current integrated value and absolute current amount in the storage device 26 (S22). Since the process in FIG. 10 is periodically and repeatedly executed, the current integrated value and the absolute current amount are updated to the most recent values each time the process in FIG. 10 is executed.

Subsequently, the SOC estimator 50 determines whether the vehicle 1 is in the ready-off state (S23). When it is determined that the ready-off state is set (YES in S23), the SOC estimator 50 derives the end-time soc in the current trip period by the current integration method, based on the current integrated value derived in step S20 (S24).

Subsequently, the SOC estimator 50 derives the absolute current amount integrated value, based on the absolute current amount derived in step S21 (S25). For example, the SOC estimator 50 adds the absolute current amount in the current trip period to the absolute charge amount integrated value up to the last-time trip period to derive the absolute current amount integrated value up to the current trip period. The SOC estimator 50 stores the end-time SOC and the absolute current amount integrated value in the storage device 26 (S26), and ends the series of processes in FIG. 10.

When it is determined that the ready-off state is not set (NO in S23), the SOC estimator 50 ends the series of processes in FIG. 10.

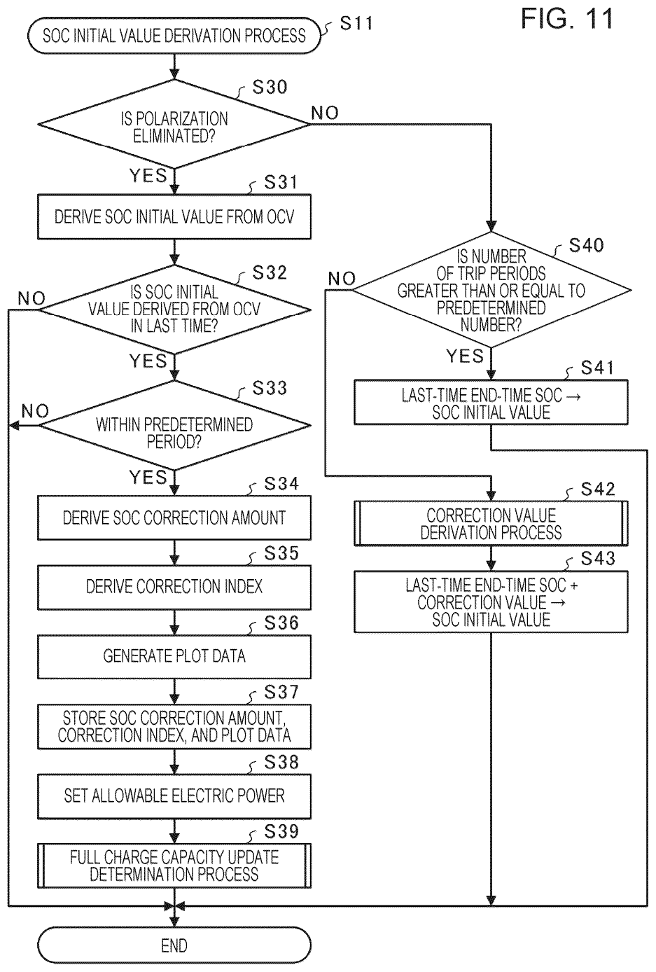

FIG. 11 is a flowchart illustrating a flow of the SOC initial value derivation process (S11). When the SOC initial value derivation process (S11) is started, the soc estimator 50 determines whether the polarization of the battery 20 is eliminated (S30). For example, the soc estimator 50 may determine that the polarization is eliminated if the elapsed time from the ready-off time point in the last-time trip period is longer than or equal to the polarization elimination time.

When it is determined that the polarization is eliminated (YES in S30), the SOC estimator 50 acquires the OCV detected by the voltage sensor 22, derives the SOC by the OCV method, and sets the derived SOC as the SOC initial value of the current trip period (S31). The SOC initial value derived in step S31 corresponds to the start-time SOC estimated by the OCV method at the start time of the current trip period.

Subsequently, the SOC estimator 50 determines whether the SOC initial value is derived from the OCV in the soc initial value derivation process (S11) at the start time of the last-time trip period, that is, at the time of the last-time ready-on (S32).

When it is determined that the SOC initial value is derived from the OCV at the start time of the last-time trip period (YES in S32), the SOC estimator 50 determines whether the preceding stop period is within the predetermined period (S33).

When it is determined that the preceding stop period is within the predetermined period (YES in S33), the soc estimator 50 derives the SOC correction amount corresponding to the last-time trip period (S34). For example, the soc estimator 50 derives the SOC correction amount by subtracting the SOC initial value derived in the current step S31 from the end-time SOC estimated by the current integration method at the end time of the last-time trip period.

Subsequently, the SOC estimator 50 divides the SOC correction amount derived in step S34 by the absolute current amount of the last-time trip period to derive the correction index corresponding to the last-time trip period (S35).

Subsequently, the SOC estimator 50 associates the correction index derived in step S35 with the absolute current amount integrated value up to the last-time trip period, and generates the plot data corresponding to the last-time trip period (S36).

Subsequently, the SOC estimator 50 stores the derived SOC correction amount, correction index, and plot data in the storage device 26 (S37).

Subsequently, the SOC estimator 50 sets the allowable electric power of the battery 20, based on the correction index derived in step S34 and the allowable electric power map stored in the at least one memory 42 (S38). The SOC estimator 50 sets larger allowable electric power as the correction index derived in step S34 is smaller.

Subsequently, the SOC estimator 50 performs a full charge capacity update determination process (S39) including a process of determining whether the full charge capacity is to be updated, and ends the SOC initial value derivation process (S11). The full charge capacity update determination process (S39) will be described in detail later.

In step S32, when it is determined that the SOC initial value is not derived from the OCV at the start time of the last-time trip period (NO in S32), the SOC estimator 50 ends the SOC initial value derivation process (S11).

In step S33, when it is determined that the preceding stop period exceeds the predetermined period (NO in S33), the SOC estimator 50 ends the SOC initial value derivation process (S11).

When it is determined in step S30 that the polarization is not eliminated (NO in S30), the SOC estimator 50 determines whether the number of trip periods in the period between the trip period of the last-time plot data and the last-time trip period is greater than or equal to the predetermined number (S40).

When it is determined that the number of trip periods in the period between the trip period of the last-time plot data and the last-time trip period is greater than or equal to the predetermined number (YES in S40), the SOC estimator 50 sets the end-time SOC derived at the end time of the last-time trip period as the SOC initial value in the current trip period (S41). Then, the SOC estimator 50 ends the SOC initial value derivation process (S11).

When it is determined that the number of trip periods in the period between the trip period of the last-time plot data and the last-time trip period is less than the predetermined number (NO in S40), the SOC estimator 50 performs a correction value derivation process (S42) for deriving the correction value. The correction value derivation process (S42) will be described in detail later.

Subsequently, the SOC estimator 50 adds the correction value derived through the correction value derivation process (S42) to the end-time SOC derived at the end time of the last-time trip period, and sets the SOC initial value in the current trip period (S43). Then, the SOC estimator 50 ends the SOC initial value derivation process (S11).

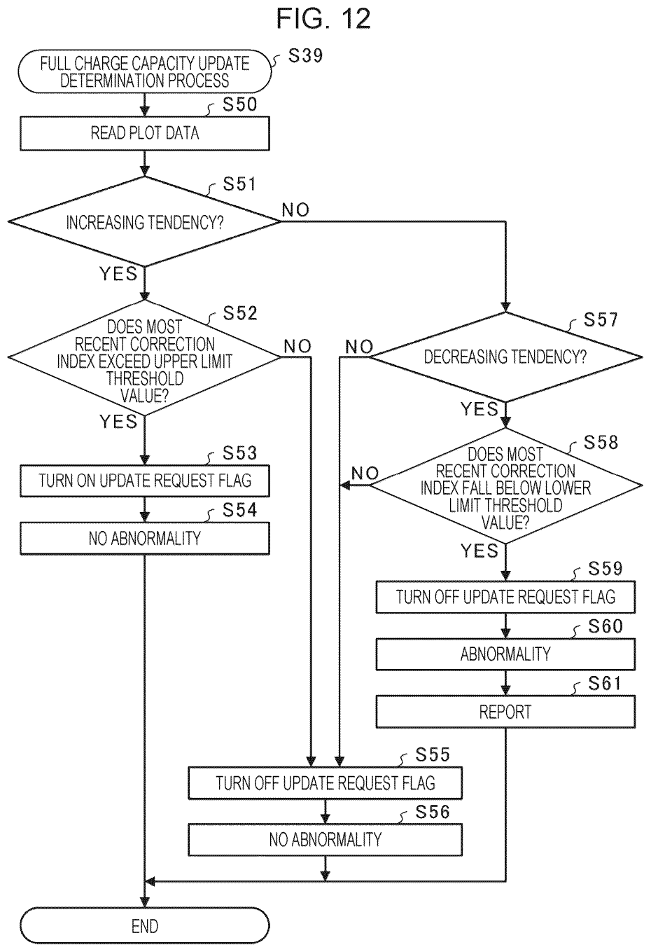

FIG. 12 is a flowchart illustrating a flow of the full charge capacity update determination process (S39). When the full charge capacity update determination process (S39) is started, the SOC estimator 50 reads, from the storage device 26, the plot data in the past after the time point of updating the full charge capacity (S50).

Subsequently, the SOC estimator 50 determines whether, in the plot data in the past, the tendency of the transition of the correction index in accordance with the transition of the absolute current amount integrated value is the increasing tendency (S51).

When it is determined that the tendency of the transition of the correction index in accordance with the transition of the absolute current amount integrated value is the increasing tendency (YES in S51), the SOC estimator 50 determines whether the most recent correction index exceeds the upper limit threshold value (S52).

When it is determined that the most recent correction index exceeds the upper limit threshold value (YES in S51), the SOC estimator 50 turns on the update request flag for requesting the update of the full charge capacity (S53). As a result, when a condition under which the full charge capacity can be derived is satisfied later, for example, when the battery 20 is fully charged, the full charge capacity is updated because the update request flag is in the ON state. Note that when the full charge capacity is updated, the update request flag is turned off.

After step S53, the SOC estimator 50 determines that there is no abnormality related to the derivation of the soc (S54), and ends the full charge capacity update determination process (S39).

When it is determined in step S52 that the most recent correction index does not exceed the upper limit threshold value (NO in S51), the SOC estimator 50 turns off the update request flag (S55). Thus, the full charge capacity is not updated.

After step S55, the SOC estimator 50 determines that there is no abnormality related to the derivation of the soc (S54), and ends the full charge capacity update determination process (S39).

When it is determined in step S51 that there is no increasing tendency (NO in S51), the SOC estimator 50 determines whether the tendency of the transition of the correction index in accordance with the transition of the absolute current amount integrated value is the decreasing tendency (S57).

When it is determined that the tendency of the transition of the correction index in accordance with the transition of the absolute current amount integrated value is the decreasing tendency (YES in S57), the SOC estimator 50 determines whether the most recent correction index falls below the lower limit threshold value (S58).

When it is determined that the most recent correction index falls below the lower limit threshold value (YES in S58), the SOC estimator 50 turns off the update request flag (S59).

After step S59, the SOC estimator 50 determines that there is an abnormality related to the derivation of the soc (S60), reports that there is an abnormality (S61), and ends the full charge capacity update determination process (S39). Note that when it is determined that there is an abnormality related to the derivation of the SOC, the SOC estimator 50 may impose the predetermined restriction on the control of the vehicle 1.

When it is determined in step S57 that there is no decreasing tendency (NO in S57), the SOC estimator 50 turns off the update instruction flag (S55). The SOC estimator 50 determines that there is no abnormality related to the derivation of the SOC (S54), and ends the full charge capacity update determination process (S39).

When it is determined in step S58 that the most recent correction index does not fall below the lower limit threshold value (NO in S58), the SOC estimator 50 turns off the update instruction flag (S55). The SOC estimator 50 determines that there is no abnormality related to the derivation of the SOC (S54), and ends the full charge capacity update determination process (S39).

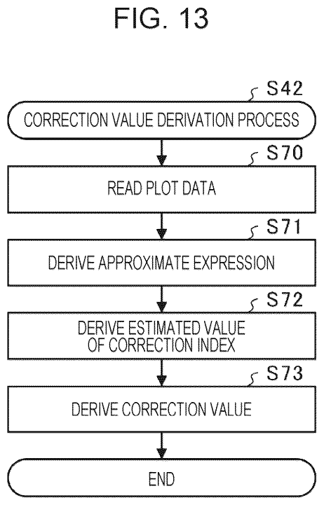

FIG. 13 is a flowchart illustrating a flow of the correction value derivation process (S42). When the correction value derivation process (S42) is started, the SOC estimator 50 reads, from the storage device 26, the plot data in the past at and after the time point of updating the full charge capacity (S70). The SOC estimator 50 derives an approximate expression of the plot data in the past (S71).

The SOC estimator 50 substitutes a value obtained by adding the differential absolute current integrated value to the absolute current amount integrated value up to the trip period of the last-time plot data in the approximate expression to derive the estimated value of the correction index (S72). The SOC estimator 50 multiplies the estimated value of the correction index by the differential absolute current amount integrated value to derive the correction value (S73), and ends the correction value derivation process (S42).

As described above, the SOC estimator 50 of the SOC estimation device 10 of the present embodiment generates the plot data in which the correction index corresponding to the trip period to which the end-time SOC belongs is associated with the absolute current integrated value up to the trip period to which the end-time SOC belongs. When the soc estimator 50 determines that the polarization of the battery 20 is not eliminated, the SOC estimator 50 derives the estimated value of the correction index corresponding to the trip period immediately before the trip period to which the current time point belongs, based on the plot data in the past. The SOC estimator 50 derives the initial value of the SOC in the trip period to which the current time point belongs, based on the estimated value of the correction index.

The correction index and the plot data in the present embodiment include information on the estimation error of the SOC from the actual SOC due to the decrease in the full charge capacity in the trip period. Thus, in the present embodiment, by deriving the SOC initial value based on the estimated value of the correction index, it is possible to derive the SOC initial value in which the influence of the decrease in the full charge capacity in the last-time trip period is reflected in the SOC initial value in the current trip period.

Therefore, according to the SOC estimation device 10 of the present embodiment, even in a state where the polarization of the battery 20 is not eliminated, it is possible to estimate an appropriate initial value of the SOC. As a result, according to the SOC estimation device 10 of the present embodiment, it is possible to improve the estimation accuracy of the SOC by the current integration method using the initial value of the SOC.

Although the embodiment of the present invention has been described above with reference to the accompanying drawings, it goes without saying that the present invention is not limited to such an embodiment. It will be apparent to those skilled in the art that various modifications or corrections can be made without departing from the scope described in the claims. It is to be understood that these are naturally included in the technical scope of the present invention.

### REFERENCE SIGNS LIST

1 vehicle
10 SOC estimation device
20 battery
30 control device
40 processor
42 memory

1. An SOC estimation device comprising:
a battery to be mounted on a vehicle; and
a control device configured to estimate an SOC of the battery, wherein
the control device comprises:
at least one processor; and
at least one memory coupled to the at least one processor,
a period from ready-on to ready-off of the vehicle is a trip period, and
the at least one processor is configured to execute a process comprising:
deriving a difference between an end-time SOC that is an SOC estimated by a current integration method at an end time of the trip period and a start-time SOC that is an SOC estimated by an open-circuit voltage method at a start time of the trip period following the trip period to which the end-time SOC belongs, as an SOC correction amount indicating an estimation error of the SOC corresponding to the trip period to which the end-time SOC belongs;
deriving an absolute current amount that is a value obtained by adding an integrated value of an absolute value of a charging current in the battery and an integrated value of an absolute value of a discharging current in the battery in the trip period;
dividing the SOC correction amount corresponding to the trip period to which the end-time SOC belongs by the absolute current amount in the trip period to which the end-time SOC belongs to derive a correction index corresponding to the trip period to which the end-time SOC belongs;
deriving an absolute current amount integrated value that is a value obtained by integrating the absolute current amount over a plurality of the trip periods from a predetermined reference time point;
generating plot data in which the correction index corresponding to the trip period to which the end-time SOC belongs is associated with the absolute current amount integrated value up to the trip period to which the end-time SOC belongs;
performing a determination of whether polarization of the battery is eliminated at the start time of the trip period;
when it is determined that the polarization of the battery is not eliminated, deriving an estimated value of the correction index corresponding to the trip period immediately before the trip period to which a current time point belongs, based on the plot data in a past; and
deriving an initial value of the SOC in the trip period to which the current time point belongs, based on the estimated value of the correction index.

2. The SOC estimation device according to claim 1, wherein
the at least one processor is configured to execute a process comprising:
multiplying a differential absolute current amount integrated value that is a difference between the absolute current amount integrated value up to the trip period immediately before the trip period to which the current time point belongs and the absolute current amount integrated value corresponding to piece of the plot data closest to the current time point among pieces of the plot data in the past, by the derived estimated value of the correction index to derive a correction value; and
adding the derived correction value to the end-time soc derived at the end time of the trip period immediately before the trip period to which the current time point belongs to derive the initial value of the SOC.

3. The SOC estimation device according to claim 1, wherein
the at least one processor is configured to execute a process comprising:
when a number of the trip periods in a period between the trip period corresponding to a piece of the plot data closest to the current time point among pieces of the plot data in the past and the trip period immediately before the trip period to which the current time point belongs is less than a predetermined number, performing a process of deriving the estimated value of the correction index and a process of deriving the initial value of the SOC, based on the estimated value of the correction index.

4. The SOC estimation device according to claim 1, wherein
the at least one processor is configured to execute a process comprising:
when it is determined that the polarization of the battery is eliminated in the determination of whether the polarization of the battery is eliminated, performing a process of deriving the SOC correction amount, a process of deriving the correction index, and a process of generating the plot data.

5. The SOC estimation device according to claim 1, wherein
the at least one processor is configured to execute a process comprising:
when it is determined that the polarization of the battery is eliminated, the SOC is estimated by the open-circuit voltage method at the start time of the trip period immediately before the trip period to which the current time point belongs, and a period from an end time point of the trip period immediately before the trip period to which the current time point belongs to the trip period to which the current time point belongs is within a predetermined period, performing a process of deriving the SOC correction amount, a process of deriving the correction index, and a process of generating the plot data.

6. The SOC estimation device according to claim 1, wherein
the at least one processor is configured to execute a process comprising:
determining whether a full charge capacity of the battery is to be updated, based on pieces of the plot data from the predetermined reference time point.

7. The SOC estimation device according to claim 6, wherein
the at least one processor is configured to execute a process comprising:
when, in the pieces of the plot data from the predetermined reference time point, a tendency of transition of the correction index in accordance with transition of the absolute current amount integrated value is an increasing tendency and the correction index that is a most recent correction index exceeds a predetermined upper limit threshold value, determining that the full charge capacity of the battery is to be updated.

8. The SOC estimation device according to claim 1, wherein
the at least one processor is configured to execute a process comprising:
determining whether an abnormality related to derivation of the SOC has occurred, based on a plurality of pieces of the plot data from the predetermined reference time point.

9. The SOC estimation device according to claim 8, wherein
the at least one processor is configured to execute a process comprising:
when, in the plurality of pieces of the plot data from the predetermined reference time point, a tendency of transition of the correction index in accordance with transition of the absolute current amount integrated value is a decreasing tendency and the correction index that is a most recent correction index falls below a predetermined lower limit threshold value, determining that the abnormality related to the derivation of the SOC has occurred.

10. The SOC estimation device according to claim 1, wherein
at least one of an upper limit value of an absolute value of electric power allowed to be input to the battery and an upper limit value of an absolute value of electric power allowed to be output from the battery is allowable electric power, and
the at least one processor is configured to execute a process comprising:
based on the derived correction index, changing a value of the allowable electric power such that the value of the allowable electric power increases as the correction index decreases.

11. The SOC estimation device according to claim 1, wherein
the at least one processor is configured to execute a process comprising:
determining whether a full charge capacity of the battery is updated; and
when it is determined that the full charge capacity of the battery is updated, resetting the absolute current amount integrated value to an initial value.

12. The SOC estimation device according to claim 1, wherein the predetermined reference time point is a time point at which a full charge capacity of the battery is updated.
